(19) United States
(12) Patent Application Publication
(10) Pub. No.: US 2025/0048934 A1
(43) Pub. Date: Feb. 6, 2025

(54) PIEZOELECTRIC THIN FILM, PIEZOELECTRIC THIN FILM ELEMENT, AND PIEZOELECTRIC TRANSDUCER

(71) Applicant: TDK Corporation, Tokyo (JP)

(72) Inventors: Junpei Morishita, Tokyo (JP); Yusuke SATO, Tokyo (JP)

(73) Assignee: TDK Corporation, Tokyo (JP)

(21) Appl. No.: 18/782,726

(22) Filed: Jul. 24, 2024

(30) Foreign Application Priority Data
Jul. 31, 2023 (JP) 2023-124586

(51) Int. Cl. H10N 30/853; H04R 17/00; H10N 30/87

(52) U.S. Cl. CPC H10N 30/8542; H10N 30/706; H10N 30/8561; H10N 30/871; H04R 17/00

(57) ABSTRACT

A piezoelectric thin film contains a metal oxide having a perovskite structure. The metal oxide contains bismuth, potassium, titanium, magnesium, iron, and an element M. The element M is at least one element selected from the group consisting of gallium and cobalt. At least a part of the metal oxide is at least one crystal selected from the group consisting of a tetragonal crystal and an orthorhombic crystal. A (001) plane of the crystal is oriented in a normal direction of a surface of the piezoelectric thin film.

### CROSS-REFERENCE TO RELATED APPLICATIONS

This application is based upon and claims the benefit of priority from Japanese Patent Application No. 2023-124586, filed On Jul. 31, 2023, the entire contents of which are incorporated herein by reference.

### BACKGROUND

### Field

The present disclosure relates to a piezoelectric thin film, a piezoelectric thin film element, and a piezoelectric transducer.

### Description of the Related Art

A piezoelectric material is processed into various piezoelectric elements in correspondence with various purposes. For example, a piezoelectric actuator converts a voltage into a force by an inverse piezoelectric effect that deforms a piezoelectric material by applying a voltage to the piezoelectric material. For example, a piezoelectric sensor converts a force into a voltage by a piezoelectric effect that deforms a piezoelectric material by applying a pressure to the piezoelectric material. These piezoelectric elements are mounted on various electronic devices. In recent markets, a decrease in size and improvement in performance of electronic devices are demanded, and thus a piezoelectric element (piezoelectric thin film element) using a piezoelectric thin film has been studied actively. However, the thinner the piezoelectric material is, the less the piezoelectric effect and the inverse piezoelectric effect are likely to be obtained. Therefore, development of a piezoelectric material having excellent piezoelectric properties in a thin film state has been expected.

Conventionally, as a piezoelectric material, lead zirconate titanate (so-called PZT) that is a perovskite-type ferroelectric material has been used frequently. However, since PZT contains lead that harms the environment or human body, development of a lead-free piezoelectric material as an alternative to PZT has been expected. For example, in Non Patent Literature 1 below, a BaTiO₃-based material is described as an example of the lead-free piezoelectric material. The BaTiO₃-based material has relatively excellent piezoelectric properties among lead-free piezoelectric materials, and thus is expected to be applied particularly to a piezoelectric thin film element.

### Non Patent Literature 1

Yiping GUO et al., “Thickness Dependence of Electrical Properties of Highly (100)-Oriented BaTiO₃ Thin Films Prepared by One-Step Chemical Solution Deposition” Japanese Journal of Applied Physics, Vol. 45, No. 2A, 2006, pp. 855-859

### SUMMARY

An object of an aspect of the present invention is to provide a piezoelectric thin film excellent in piezoelectric properties, a piezoelectric thin film element containing the piezoelectric thin film, and a piezoelectric transducer containing the piezoelectric thin film or the piezoelectric thin film element.

For example, an aspect of the present invention relates to a piezoelectric thin film described in any one of [1] to [5] below, a piezoelectric thin film element described in any one of [6] to [14] below, and a piezoelectric transducer described in any one of [15] and [16] below.
[1]A piezoelectric thin film containing a metal oxide having a perovskite structure, wherein
the metal oxide contains bismuth, potassium, titanium, magnesium, iron, and an element M,
the element M is at least one element selected from the group consisting of gallium and cobalt,
at least a part of the metal oxide is at least one crystal selected from the group consisting of a tetragonal crystal and an orthorhombic crystal, and
a (001) plane of the crystal is oriented in a normal direction of a surface of the piezoelectric thin film.
[2] The piezoelectric thin film described in [1], wherein the metal oxide is represented by Chemical Formula 1 below,
each of x, y, and z in Chemical Formula 1 below is a positive real number,
x+y+z is 1,
α in Chemical Formula 1 below is more than 0 and less than 1,
β in Chemical Formula 1 below is more than 0 and less than 1,
γ in Chemical Formula 1 below is from 0.05 to 0.40,
M in Chemical Formula 1 below is represented by Ga_{1-δ}Co_{δ}, and
δ is from 0 to 1:

x(B_{1-α}K_{α})TiO₃-yBi(Ti_{1-β}Mg_{β})O₃-zBi(Fe_{1-γ}M_{γ})O₃ (1)
[3] The piezoelectric thin film described in [2], wherein a three-dimensional coordinate system is composed of an X-axis, a Y-axis, and a Z-axis,
arbitrary coordinates in the coordinate system are represented by (X, Y, Z),
coordinates (x, y, z) in the coordinate system correspond to x, y, and z in Chemical Formula 1,
coordinates A in the coordinate system are (0.250, 0.005, 0.700),
coordinates B in the coordinate system are (0.450, 0.250, 0.300),
coordinates C in the coordinate system are (0.200, 0.500, 0.300),
coordinates D in the coordinate system are (0.005, 0.250, 0.700), and
the coordinates (x, y, z) are positioned within a quadrangle with vertexes at the coordinates A, the coordinates B, the coordinates C, and the coordinates D.
[4] The piezoelectric thin film described in any one of [1] to [3], wherein the piezoelectric thin film is an epitaxial film.
[5] The piezoelectric thin film described in any one of [1] to [4], wherein the piezoelectric thin film is a ferroelectric thin film.
[6]A piezoelectric thin film element containing the piezoelectric thin film described in any one of [1] to [5].
[7] The piezoelectric thin film element described in [6], containing:
a crystalline substrate; and
the piezoelectric thin film directly or indirectly stacked on the crystalline substrate.
[8] The piezoelectric thin film element described in [6], containing:
a crystalline substrate; and
an electrode layer directly or indirectly stacked on the crystalline substrate; and
the piezoelectric thin film directly or indirectly stacked on the electrode layer.
[9] The piezoelectric thin film element described in [6], containing:
an electrode layer; and
the piezoelectric thin film directly or indirectly stacked on the electrode layer.
[10] The piezoelectric thin film element described in [8], further containing at least one intermediate layer (first intermediate layer), wherein
the intermediate layer (first intermediate layer) is disposed between the crystalline substrate and the electrode layer.
[11] The piezoelectric thin film element described in [8], further containing at least one intermediate layer (second intermediate layer), wherein
the intermediate layer (second intermediate layer) is disposed between the electrode layer and the piezoelectric thin film.
[12] The piezoelectric thin film element described in [9], further containing at least one intermediate layer (second intermediate layer), wherein
the intermediate layer (second intermediate layer) is disposed between the electrode layer and the piezoelectric thin film.
[13] The piezoelectric thin film element described in [8] or [11], wherein the electrode layer contains a platinum crystal,
a (002) plane of the platinum crystal is oriented in a normal direction of a surface of the electrode layer, and
a (200) plane of the platinum crystal is oriented in an in-plane direction of the surface of the electrode layer.
[14] The piezoelectric thin film element described in [9] or [12], wherein the electrode layer contains a platinum crystal,
a (002) plane of the platinum crystal is oriented in a normal direction of a surface of the electrode layer, and
a (200) plane of the platinum crystal is oriented in an in-plane direction of the surface of the electrode layer.
[15]A piezoelectric transducer containing the piezoelectric thin film described in any one of [1] to [5].
[16]A piezoelectric transducer containing the piezoelectric thin film element described in any one of [6] to [14].

According to an aspect of the present invention, there are provided a piezoelectric thin film excellent in piezoelectric properties, a piezoelectric thin film element containing the piezoelectric thin film, and a piezoelectric transducer containing the piezoelectric thin film or the piezoelectric thin film element.

### BRIEF DESCRIPTION OF THE DRAWINGS

FIG. 1A is a schematic cross-sectional view of a piezoelectric thin film element according to a specific example of the present invention, FIG. 1B is an exploded perspective view of the piezoelectric thin film element illustrated in FIG. 1A, and a substrate, a first intermediate layer, a second intermediate layer, and a second electrode layer are omitted in FIG. 1B.

FIG. 2 is a perspective view of a crystal (unit cell) of a metal oxide having a perovskite structure and shows arrangement of each element in the perovskite structure.

FIG. 3 is a perspective view of a crystal (unit cell) of a metal oxide having a perovskite structure and shows lattice planes and crystal orientations of the crystal.

FIG. 4 is a three-dimensional coordinate system for showing a composition of a piezoelectric thin film.

FIG. 5 is a triangular coordinate system corresponding to a triangle shown in FIG. 4.

FIG. 6 is a schematic cross-sectional view of a piezoelectric thin film element (ultrasonic transducer) according to another specific example of the present invention.

### DETAILED DESCRIPTION

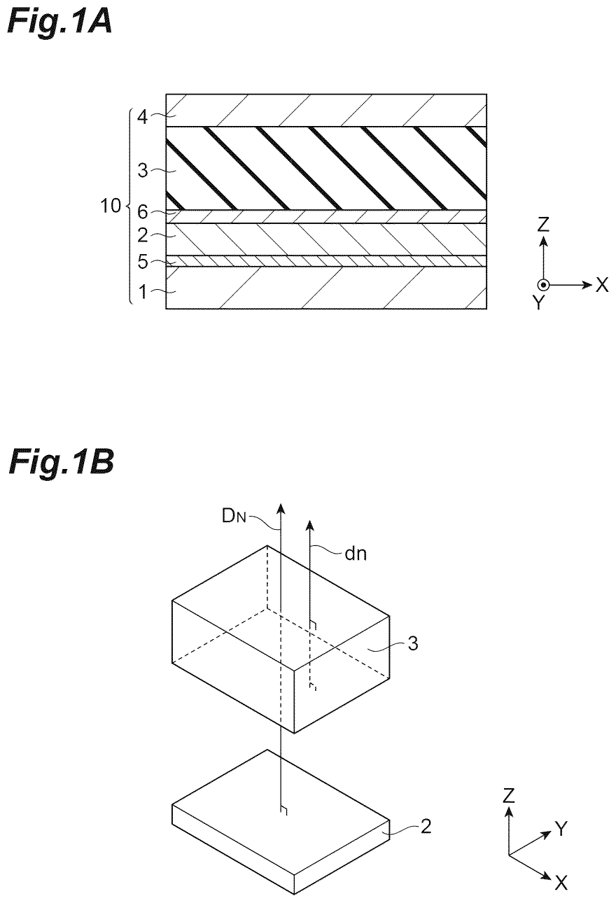

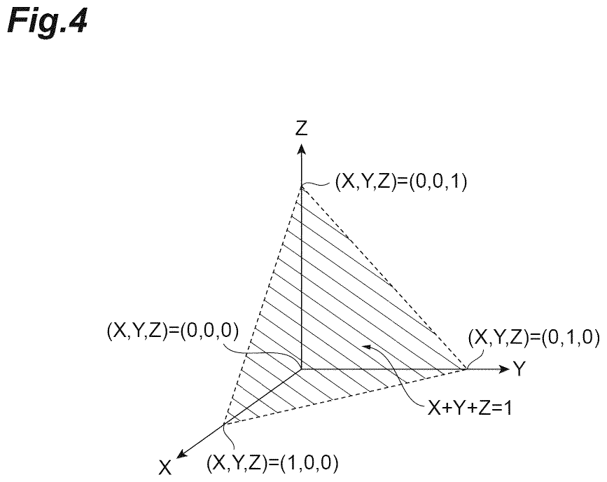

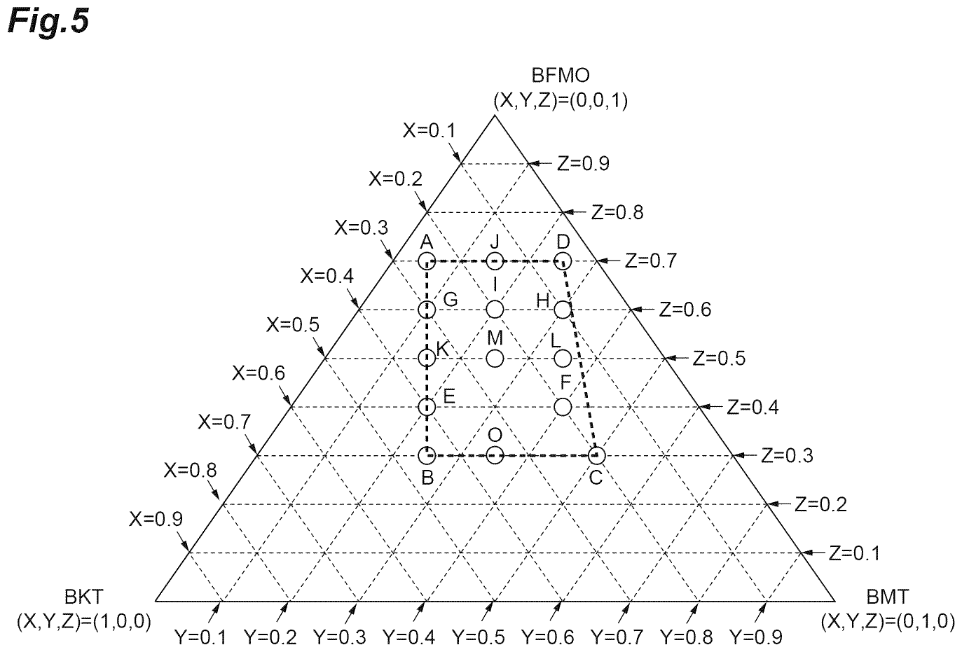

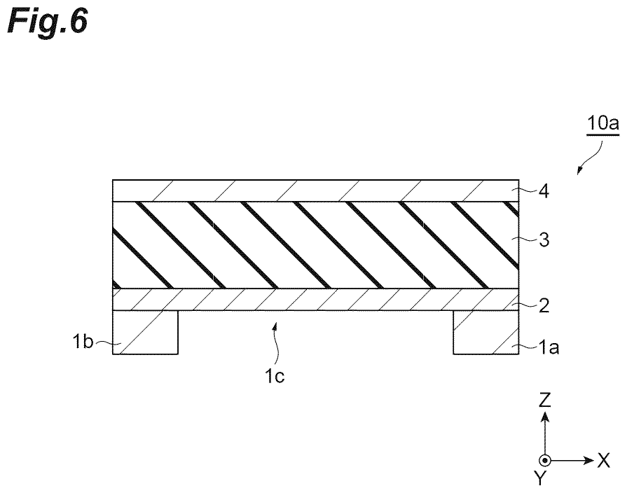

Hereinafter, details of a preferred embodiment of the present invention will be described with reference to the drawings. However, the present invention is not limited to the following embodiment. In the following description, with reference to the drawings, the same reference numbers are assigned to the same components or to similar components having the same function, and overlapping description is omitted. An X-axis, a Y-axis and a Z-axis shown in FIG. 1A, FIG. 1B, and FIG. 6 are three coordinate axes orthogonal to one another. The X-axis, Y-axis and Z-axis are common to FIG. 1A, FIG. 1B, and FIG. 6, but the coordinate systems shown in FIG. 1A, FIG. 1B, and FIG. 6 have nothing to do with the coordinate systems shown in FIG. 4 and FIG. 5.

### (Piezoelectric Thin Film Element)

A piezoelectric thin film element according to the present embodiment contains at least a piezoelectric thin film. For example, as illustrated in FIG. 1A, a piezoelectric thin film element 10 according to the present embodiment may contain a crystalline substrate 1, a first electrode layer 2 (lower electrode layer) directly or indirectly stacked on the crystalline substrate 1, a piezoelectric thin film 3 directly or indirectly stacked on the first electrode layer 2, and a second electrode layer 4 (upper electrode layer) directly or indirectly stacked on the piezoelectric thin film 3. The piezoelectric thin film element 10 may further contain at least one intermediate layer. For example, the piezoelectric thin film element 10 may contain a first intermediate layer 5. The first intermediate layer 5 may be disposed between the crystalline substrate 1 and the first electrode layer 2, and the first electrode layer 2 may be directly stacked on a surface of the first intermediate layer 5. The piezoelectric thin film element 10 may contain a second intermediate layer 6. The second intermediate layer 6 may be disposed between the first electrode layer 2 and the piezoelectric thin film 3, and the piezoelectric thin film 3 may be directly stacked on a surface of the second intermediate layer 6. A thickness of each of the crystalline substrate 1, the first intermediate layer 5, the first electrode layer 2, the second intermediate layer 6, the piezoelectric thin film 3, and the second electrode layer 4 may be uniform. As illustrated in FIG. 1B, a normal direction dn of a surface of the piezoelectric thin film 3 may be substantially or completely parallel to a normal direction D_{N} of a surface of the first electrode layer 2. That is, the surface of the piezoelectric thin film 3 may be substantially or completely parallel to the surface of the first electrode layer 2. The normal direction dn of the surface of the piezoelectric thin film 3 may be a polarization direction of the piezoelectric thin film 3. The normal direction dn of the surface of the piezoelectric thin film 3 may be restated as a thickness direction of the piezoelectric thin film 3.

A modified example of the piezoelectric thin film element 10 does not have to contain the crystalline substrate 1. For example, the crystalline substrate 1 may be removed after the formation of the first electrode layer 2, the piezoelectric thin film 3, and the second electrode layer 4. In a case where the crystalline substrate 1 functions as an electrode, the crystalline substrate 1 may be the first electrode layer 2. That is, in a case where the crystalline substrate 1 functions as an electrode, the modified example of the piezoelectric thin film element 10 may contain the crystalline substrate 1 and the piezoelectric thin film 3 stacked on the crystalline substrate 1. In a case where the crystalline substrate 1 functions as an electrode, the piezoelectric thin film 3 may be directly stacked on the crystalline substrate 1. In a case where the crystalline substrate 1 functions as an electrode, the piezoelectric thin film 3 may be stacked on the crystalline substrate 1 through at least one of the first intermediate layer 5 and the second intermediate layer 6.

The piezoelectric thin film 3 contains a metal oxide having a perovskite structure. The metal oxide contains bismuth (Bi), potassium (K), titanium (Ti), magnesium (Mg), iron (Fe), and an element M. The element M is at least one element selected from the group consisting of gallium (Ga) and cobalt (Co). The metal oxide having the above composition tends to be at least one crystal selected from the group consisting of a tetragonal crystal and an orthorhombic crystal, and a (001) plane of the crystal tends to be oriented in the normal direction of the surface of the piezoelectric thin film. As a result, the piezoelectric thin film 3 can have excellent piezoelectric properties (large piezoelectric strain constant d_{33,f}) and ferroelectricity.

The metal oxide may consist only of Bi, K, Ti, Mg, Fe, the element M, and oxygen (O). The metal oxide may contain other elements in addition to Bi, K, Ti, Mg, Fe, the element M, and O. The metal oxide may further contain at least one element selected from the group consisting of lanthanum (La), yttrium (Y), sodium (Na), lithium (Li), zirconium (Zr), nickel (Ni), zinc (Zn), manganese (Mn), and lead (Pb). However, the metal oxide does not have to contain Pb.

The metal oxide is a main component of the piezoelectric thin film 3. A ratio of all elements constituting the metal oxide in the piezoelectric thin film 3 may be from 99 mol % to 100 mol %. The piezoelectric thin film 3 may consist only of the metal oxide. The piezoelectric thin film 3 may contain other elements in addition to Bi, K, Ti, Mg, Fe, the element M, and O as long as the piezoelectric properties of the piezoelectric thin film 3 are not impaired. For example, the piezoelectric thin film 3 may further contain at least one element selected from the group consisting of La, Y, Na, Li, Zr, Ni, Zn, Mn, and Pb. However, the piezoelectric thin film 3 does not have to contain Pb.

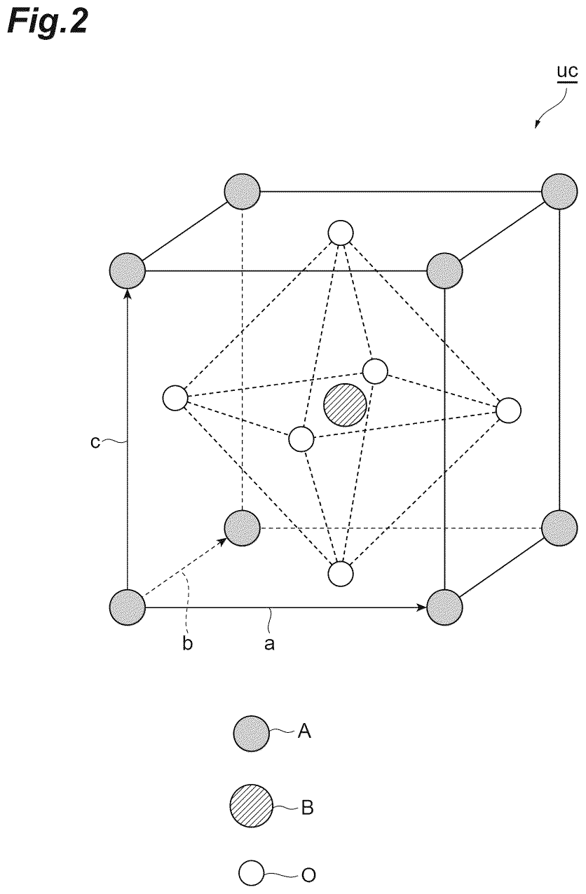

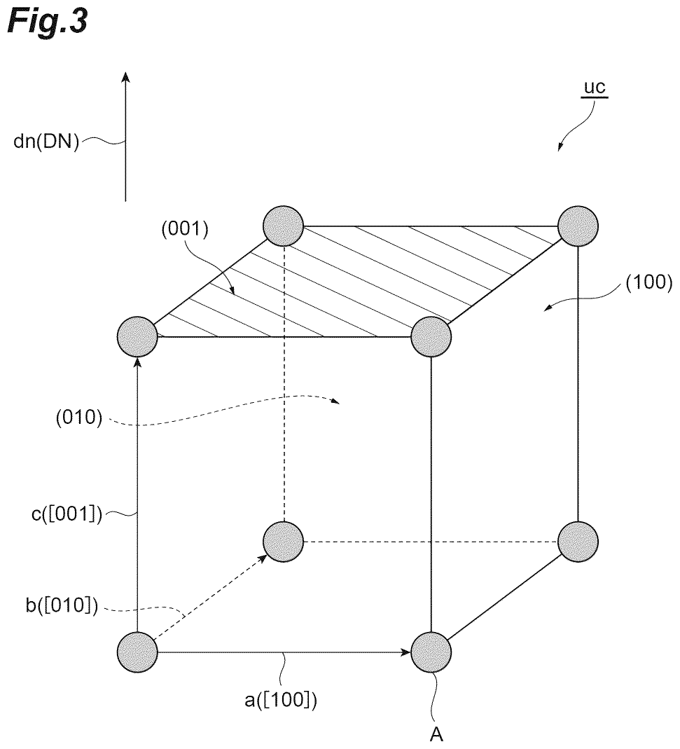

Hereinafter, the metal oxide having a perovskite structure is referred to as a “perovskite-type oxide”. FIG. 2 shows a unit cell of a crystal of the perovskite-type oxide. An element located in the A site of the unit cell uc may be Bi or K. An element located in the B site of the unit cell uc may be Ti, Mg, Fe, or the element M. The unit cell uc shown in FIG. 2 is the same as the unit cell uc shown in FIG. 3. However, the B site and oxygen (O) in the unit cell uc are omitted in FIG. 3 to show lattice planes. A lattice translation vector a (namely, a-axis) in the unit cell uc faces a [100] direction, a lattice translation vector b (namely, b-axis) in the unit cell uc faces a [010] direction, and a lattice translation vector c (namely, c-axis) in the unit cell uc faces a [001] direction. The lattice translation vector a, the lattice translation vector b, and the lattice translation vector c are perpendicular to one another. A length a of the lattice translation vector a is a spacing a (lattice constant a) of (100) planes of the perovskite-type oxide. A length b of the lattice translation vector b is a spacing b (lattice constant b) of (010) planes of the perovskite-type oxide. A length c of the lattice translation vector c is a spacing c (lattice constant c) of (001) planes of the perovskite-type oxide. The piezoelectric thin film 3 may consist of a single crystal of the perovskite-type oxide. The piezoelectric thin film 3 may consist of a polycrystal of the perovskite-type oxide.

A part or the whole of the perovskite-type oxide is at least one crystal selected from the group consisting of a tetragonal crystal and an orthorhombic crystal at normal temperature or at a temperature of Curie temperature or less. Due to the anisotropy along the c-axis of either the tetragonal or orthorhombic crystal, the piezoelectric thin film 3 can have excellent piezoelectric properties and ferroelectricity. In the tetragonal crystal, the lattice constant a is equal to the lattice constant b. In the tetragonal crystal, the lattice constant a is different from the lattice constant c. In the tetragonal crystal, the lattice constant c may be larger than the lattice constant a. In the orthorhombic crystal, the lattice constant a, the lattice constant b, and the lattice constant c are different from each other. In the orthorhombic crystal, the lattice constant c may be larger than each of the lattice constant a and the lattice constant b. The perovskite-type oxide may consist only of the tetragonal crystal. The perovskite-type oxide may consist only of the orthorhombic crystal. The perovskite-type oxide may consist only of the tetragonal crystal and the orthorhombic crystal. The piezoelectric thin film 3 may further contain a crystal other than the tetragonal crystal and the orthorhombic crystal. For example, the piezoelectric thin film 3 may further contain one or both of a cubic crystal of a perovskite-type oxide and a rhombohedral crystal of a perovskite-type oxide.

A (001) plane of at least one crystal selected from the group consisting of the tetragonal crystal and the orthorhombic crystal is oriented in the normal direction dn of the surface of the piezoelectric thin film 3. The piezoelectric thin film 3 may contain a plurality of crystals, and the (001) plane of a part or all of the crystals in the piezoelectric thin film 3 may be oriented in the normal direction dn of the surface of the piezoelectric thin film 3. For example, the (001) plane of the crystal (unit cell uc) may be substantially or completely perpendicular to the normal direction dn, and [001](orientation of the lattice plane) of the crystal (unit cell uc) may be substantially or completely parallel to the normal direction dn. In other words, the (001) plane of the crystal (unit cell uc) may be substantially or completely parallel to the surface of the piezoelectric thin film 3. A crystal orientation in which the perovskite-type oxide having the above-described composition is easily polarized is [001]. Therefore, thus the piezoelectric thin film 3 can have excellent piezoelectric properties and ferroelectricity due to the (001) plane of the crystal of the perovskite-type oxide being oriented in the normal direction dn of the surface of the piezoelectric thin film 3. For the same reason, for example, c/a of each of the tetragonal crystal and the orthorhombic crystal may be from 1.05 to 1.20. For example, the lattice constant a of each of the tetragonal crystal and the orthorhombic crystal may be from 0.375 Å to 0.395 Å. The lattice constant b of the tetragonal crystal is equal to the lattice constant a of the tetragonal crystal. For example, the lattice constant b of the orthorhombic crystal may be from 0.375 Å to 0.395 Å and may be a value different from the lattice constant a of the orthorhombic crystal. For example, the lattice constant c of each of the tetragonal crystal and the orthorhombic crystal may be from 0.430 Å to 0.450 Å. c/a of the tetragonal crystal may be the same as or different from c/a of the orthorhombic crystal. The lattice constant a of the tetragonal crystal may be the same as or different from the lattice constant a of the orthorhombic crystal. The lattice constant c of the tetragonal crystal may be the same as or different from the lattice constant c of the orthorhombic crystal.

A degree of orientation of each lattice plane of the crystal may be quantified by an orientation degree (unit: %). The orientation degree of each lattice plane may be calculated based on a diffracted X-ray peak derived from each lattice plane. The diffracted X-ray peak derived from each lattice plane may be measured by out-of-plane measurement in the surface of the piezoelectric thin film 3. An orientation degree of the (001) plane may be represented as 100×I₍₀₀₁₎/ΣI₍ₕₖₗ₎. An orientation degree of the (110) plane may be represented as 100×I₍₁₁₀₎/ΣI₍ₕₖₗ₎. An orientation degree of the (111) plane may be represented as 100×I₍₁₁₁₎/ΣI₍ₕₖₗ₎. I₍₀₀₁₎ is a maximum value of the diffracted X-ray peak derived from the (001) plane. I₍₁₁₀₎ is a maximum value of the diffracted X-ray peak derived from the (110) plane. I₍₁₁₁₎ is a maximum value of the diffracted X-ray peak derived from the (111) plane. ΣI₍ₕₖₗ₎ is I₍₀₀₁₎+I₍₁₁₀₎+I₍₁₁₁₎. The orientation degree of the (001) plane may be represented as 100×S₍₀₀₁₎/ΣS₍ₕₖₗ₎. The orientation degree of the (110) plane may be represented as 100×S₍₁₁₀₎/ΣS₍ₕₖₗ₎. The orientation degree of the (111) plane may be represented as 100×S₍₁₁₁₎/ΣS₍ₕₖₗ₎. S₍₀₀₁₎ is an area (integration of a peak) of the diffracted X-ray peak derived from the (001) plane. S₍₁₁₀₎ is an area (integration of the peak) of the diffracted X-ray peak derived from the (110) plane. S₍₁₁₁₎ is an area (integration of the peak) of the diffracted X-ray peak derived from the (111) plane. ΣS₍ₕₖₗ₎ is S₍₀₀₁₎+S₍₁₁₀₎+S₍₁₁₁₎. The degree of orientation of each lattice plane may be quantified by an orientation degree based on the Lotgering method.

For the reason that the piezoelectric thin film 3 is likely to have excellent piezoelectric properties and ferroelectricity, it is preferable that the (001) plane of the crystal is preferentially oriented in the normal direction dn of the surface of the piezoelectric thin film 3. That is, the orientation degree of the (001) plane is preferably higher than the orientation degree of each of the (110) plane and the (111) plane. For example, the orientation degree of the (001) plane may be from 70% to 100%, preferably from 80% to 100%, and more preferably from 90% to 100%.

In contrast to the piezoelectric thin film 3, it is difficult to strain a bulk of a piezoelectric material having a cubic crystal structure or a pseudo-cubic crystal structure to make the bulk of the piezoelectric material into a tetragonal crystal or an orthorhombic crystal. Therefore, there is a tendency that the bulk of the piezoelectric material is difficult to have piezoelectric properties attributable to the tetragonal crystal or orthorhombic crystal of the perovskite-type oxide.

A crystalline orientation described below means that the (001) plane of at least one crystal selected from the group consisting of a tetragonal crystal and an orthorhombic crystal is oriented in the normal direction dn of the surface of the piezoelectric thin film 3.

The piezoelectric thin film 3 is a crystalline film formed by a vapor deposition method or a solution method, and is likely to have the above-described crystalline orientation. On the other hand, there is a tendency that a bulk of the piezoelectric material having the same composition as that of the piezoelectric thin film 3 is difficult to have the above-described crystalline orientation as compared to the piezoelectric thin film 3. This is because the bulk of the piezoelectric material is a sintered body (ceramic) made from a powder containing essential elements of the piezoelectric material, and it is difficult to control structure and orientation of numerous crystals constituting the sintered body. Since the bulk of the piezoelectric material contains Fe, a specific resistivity of the bulk of the piezoelectric material is lower than that of the piezoelectric thin film 3. As a result, a leakage current is likely to occur in the bulk of the piezoelectric material. Therefore, it is difficult to polarize the bulk of the piezoelectric material by applying a high electric field, and it is difficult for the bulk of the piezoelectric material to have the same piezoelectric properties as those of the piezoelectric thin film.

The metal oxide contained in the piezoelectric thin film 3 may be represented by Chemical Formula 1 below. Chemical Formula 1 below is substantially the same as Chemical Formula 1a below and Chemical Formula 1b below. M in Chemical Formula 1 and Chemical Formula 1a below is represented as Ga_{1-δ}Co_{δ}. (Bi_{1-α}K_{α})_{z}Bi_{y+z} in Chemical Formula 1a and Chemical Formula 1b corresponds to the A site of the unit cell uc of the perovskite-type oxide (ABO₃). Tiₓ(Ti_{1-β}Mg_{β})_{y}(Fe_{1-γ}M_{γ})_{z} in Chemical Formula 1a corresponds to the B site of the unit cell uc of the perovskite-type oxide. Tiₓ(Ti_{1-β}Mg_{β})_{y}(Fe_{1-γ}(Ga_{1-δ}Co_{δ})_{γ})_{z} in Chemical Formula 1b below corresponds to the B site of the unit cell uc of the perovskite-type oxide. In a case where the metal oxide is represented by Chemical Formula 1 below, the piezoelectric thin film 3 is likely to contain at least one crystal selected from the group consisting of a tetragonal crystal and an orthorhombic crystal, the crystal is likely to have the above-described crystalline orientation, and the piezoelectric thin film 3 is likely to have excellent piezoelectric properties and ferroelectricity.

x(Bi_{1-α}K_{α})TiO₃-yBi(Ti_{1-β}Mg_{β})O₃-zBi(Fe_{1-γ}M_{γ})O₃ (1)

(Bi_{1-α}K_{α})ₓBi_{y+z}Tiₓ(Ti_{1-β}Mg_{β})_{y}(Fe_{1-γ}M_{γ})_{z}O_{3±ε} (1a)

(Bi_{1-α}K_{α})ₓBi_{y+z}Tiₓ(Ti_{1-β}Mg_{β})_{y}(Fe_{1-γ}(Ga_{1-δ}Co_{δ})_{γ})_{z}O_{3γε} (1b)

A unit of each of x, y, z, α, β, γ, δ, and ε in each chemical formula described above is mole or molar ratio. Each of x, y, and z is a positive real number. x+y+z is 1.000. x in each chemical formula is more than 0.000 and less than 1.000. y in each chemical formula is more than 0.000 and less than 1.000. z in each chemical formula is more than 0.000 and less than 1.000. α in each chemical formula is more than 0.000 and less than 1.000 as long as the crystalline structure of the perovskite-type oxide is maintained. β in each chemical formula is more than 0.000 and less than 1.000 as long as the crystalline structure of the perovskite-type oxide is maintained. For example, α may be 0.500, and β may be 0.500. γ in each chemical formula is from 0.050 to 0.400, 6 in each chemical formula is from 0.000 to 1.000.

In a case where γ in each chemical formula is from 0.050 to 0.400, the piezoelectric thin film 3 is likely to contain at least one crystal selected from the group consisting of a tetragonal crystal and an orthorhombic crystal, the crystal is likely to have the above-described crystalline orientation, and the piezoelectric thin film 3 is likely to have excellent piezoelectric properties and ferroelectricity.

A total value of amounts of substance of Bi and K in the metal oxide may be represented as [A] mole, a total value of amounts of substance of Ti, Mg, Fe, and the element M in the metal oxide may be represented as [B] mole, and [A]/[B] may be 1.000. [A]/[B] may be a value other than 1.000 as long as the metal oxide may have a perovskite structure. That is, [A]/[B] may be less than 1.000, or may be more than 1.000. ε in Chemical Formula 1a and Chemical Formula 1b is 0.000 or more. ε may be a value other than 0.000 as long as the metal oxide may have a perovskite structure. For example, ε may be more than 0.000 and 1.000 or less. ε may be calculated from a valence of each of the element at the A site and the element at the B site of the perovskite structure. The valence of each element may be measured by X-ray photoelectron spectroscopy (XPS).

In the following, (Bi_{1-α}K_{α})TiO₃ is referred to as BKT. Bi(Ti_{1-β}Mg_{β})O₃ is referred to as BMT. BiFe_{1-γ}M_{γ}O₃ is referred to as BFMO. BiFeO₃ is referred to as BFO. A metal oxide having a composition represented by the sum of BKT and BMT is referred to as BKT-BMT. A metal oxide having a composition represented by the sum of BKT, BMT, and BFO is referred to as BKT-BMT-BFO. A metal oxide having a composition represented by Chemical Formula 1 above is referred to as xBKT-yBMT-zBFMO. The crystal of each of BKT, BMT, BFMO, BFO, BKT-BMT, BKT-BMT-BFO, and xBKT-yBMT-zBFMO has a perovskite structure.

Both of bismuth gallate (BiGaO₃; BGO) and bismuth cobaltate (BiCoO₃; BCO) are a perovskite-type oxide. c/a of the crystal (tetragonal crystal) of each of bismuth gallate and bismuth cobaltate is larger than c/a of the crystal (rhombohedral crystal) of BFO. In xBKT-yBMT-zBFMO, since a part of BFO is substituted with one or both of BGO and BCO, c/a of the crystal of xBKT-yBMT-zBFMO tends to be larger than c/a of conventional BKT-BMT-BFO. As a result, the piezoelectric thin film 3 containing xBKT-yBMT-zBFMO can have excellent piezoelectric properties and ferroelectricity.

The crystal of BKT is a tetragonal crystal at normal temperature, and BKT is a ferroelectric material. The crystal of BMT is a rhombohedral crystal at normal temperature, and BMT is a ferroelectric material. The crystal of BFO is a rhombohedral crystal at normal temperature, and BFO is a ferroelectric material. A thin film consisting of BKT-BMT is a tetragonal crystal at normal temperature. c/a of the tetragonal crystal of BKT-BMT tends to be larger than c/a of BKT. The thin film consisting of BKT-BMT is excellent in ferroelectricity as compared to a thin film consisting of BKT and a thin film consisting of BMT. A thin film consisting of xBKT-yBMT-zBFMO tends to be at least one of a tetragonal crystal and an orthorhombic crystal at normal temperature. c/a of xBKT-yBMT-zBFMO tends to be larger than c/a of each of BKT-BMT and BKT-BMT-BFO. The thin film consisting of xBKT-yBMT-zBFMO is excellent in ferroelectricity as compared to a thin film consisting of BKT-BMT or BKT-BMT-BFO. That is, the piezoelectric thin film 3 containing xBKT-yBMT-zBFMO is likely to be a ferroelectric thin film. It is presumed that the ferroelectricity of the piezoelectric thin film 3 is attributable to the composition of xBKT-yBMT-zBFMO having a morphotropic phase boundary (MPB). However, since the piezoelectric thin film 3 belongs to a tetragonal crystal system or an orthorhombic crystal system, it is presumed that the ferroelectricity of the piezoelectric thin film 3 is not attributable to MPB alone. Since the piezoelectric thin film 3 has ferroelectricity, the piezoelectric thin film 3 is likely to have large d_{33,f}. In contrast to the piezoelectric thin film 3, the crystal contained in the bulk of xBKT-yBMT-zBFMO is a pseudo-cubic crystal, and there is a tendency that the bulk of xBKT-yBMT-zBFMO is difficult to have the above-described crystalline orientation and ferroelectricity as compared to the piezoelectric thin film 3.

The composition of xBKT-yBMT-zBFMO may be represented based on a three-dimensional coordinate system. As shown in FIG. 4, The three-dimensional coordinate system is composed of an X-axis, a Y-axis, and a Z-axis. Arbitrary coordinates in the coordinate system are represented by (X, Y, Z). Coordinates (x, y, z) in the coordinate system correspond to x, y, and z in Chemical Formula 1 above. A sum of x, y, and z in Chemical Formula 1 is 1, and any of x, y, and z are positive real numbers. Therefore, the coordinates (x, y, z) are positioned inside a triangle drawn by dotted lines in a plane represented by X+Y+Z=1. That is, the coordinates (x, y, z) are positioned inside a triangle with vertexes at the coordinates (1, 0, 0), the coordinates (1, 1, 0), and the coordinates (0, 0, 1). This triangle is a triangular coordinate system, and X+Y+Z is 1 in the triangular coordinate system. The triangular coordinate system is shown in FIG. 5. The triangular coordinate system contains coordinates A, coordinates B, coordinates C, and coordinates D in addition to the coordinates (x, y, z). That is, any of the coordinates (x, y, z), the coordinates A, the coordinates B, the coordinates C, the coordinates D, the coordinates E, and the coordinates F are positioned in the plane represented by X+Y+Z=1. The coordinates A are (0.250, 0.005, 0.700). The coordinates B are (0.450, 0.250, 0.300). The coordinates C are (0.200, 0.500, 0.300). The coordinates D are (0.005, 0.250, 0.700). The coordinates (x, y, z) indicating x, y, and z in Chemical Formula 1 may be positioned within a quadrangle with vertexes at the coordinates A, the coordinates B, the coordinates C, and the coordinates D. In a case where the coordinates (x, y, z) are within the quadrangle ABCD, the composition of xBKT-yBMT-zBFMO is likely to have MPB, and the piezoelectric properties and the ferroelectricity of the piezoelectric thin film 3 are likely to be improved. In a case where x is equal to y, the coordinates (x, y, z) are positioned on a straight line passing through coordinates (0.500, 0.500, 0.000) and coordinates (0.000, 0.000, 1.000). In a case where x is equal toy, the composition of xBKT-yBMT-zBFMO is likely to have MPB, and the piezoelectric properties and the ferroelectricity of the piezoelectric thin film 3 are likely to be improved.

x may be from 0.050 to 0.450, or from 0.100 to 0.350, y may be from 0.050 to 0.500, or from 0.100 to 0.350, and z may be from 0.300 to 0.700. In a case where x, y, and z are in the ranges described above and x+y+z is 1, the composition of xBKT-yBMT-zBFMO is likely to have MPB, and the piezoelectric properties and the ferroelectricity of the piezoelectric thin film 3 are likely to be improved.

For example, a thickness of the piezoelectric thin film 3 may be from 10 nm to 10 μm, from 0.3 μm to 10 μm, from 0.3 μm to 5 μm, from 0.5 μm to 5 μm, from 0.3 μm to 3 μm, or from 0.5 μm to 3 μm. For example, an area of the piezoelectric thin film 3 may be from 1 μm² to 500 mm². An area of each of the crystalline substrate 1, the first intermediate layer 5, the first electrode layer 2, the second intermediate layer 6, and the second electrode layer 4 may be the same as or different from the area of the piezoelectric thin film 3.

For example, the composition of the piezoelectric thin film 3 may be analyzed by X-Ray fluorescence spectroscopy (XRF method) or inductively coupled plasma (ICP) emission spectroscopy. The crystalline structure and the crystalline orientation of the piezoelectric thin film 3 may be specified by an X-ray diffraction (XRD) method.

For example, the piezoelectric thin film 3 may be formed by the following method.

As a raw material for the piezoelectric thin film 3, a target having the same composition as that of the piezoelectric thin film 3 may be used. A method for producing the target is as follows.

As starting materials, for example, powder of each of bismuth oxide (Bi₂O₃), potassium carbonate (K₂CO₃), titanium oxide (TiO₂), magnesium oxide (MgO), iron oxide (Fe₂O₃), and an oxide of the element M may be used. The oxide of the element M may be at least one oxide selected from the group consisting of gallium oxide (Ga₂O₃) and cobalt oxide (Co₂O₃). As starting materials, instead of the oxides described above, materials to become oxides by sintering such as carbonates or oxalates may be used. These starting materials are sufficiently dried at 100° C. or more, and then each of the starting materials is weighed such that the amount of substance (molar ratio) of each of Bi, K, Ti, Mg, Fe, and the element M is within the range specified in Chemical Formula 1, Chemical Formula 1a, or Chemical Formula 1b described above. In the vapor deposition method described later, Bi and K in the target are likely to volatilize as compared to other elements. Therefore, the molar ratio of Bi in the target may be adjusted to a value higher than the molar ratio of Bi in the piezoelectric thin film 3. The molar ratio of K in the target may be adjusted to a value higher than the molar ratio of K in the piezoelectric thin film 3.

The weighed starting materials are sufficiently mixed in an organic solvent or water. A mixing time may be from 5 hours to 20 hours. A mixing means may be a ball mill. The starting materials obtained after mixing are sufficiently dried, and then the starting materials are molded with a pressing machine. The molded starting materials are calcined to obtain a calcined product. A calcining temperature may be from 750° C. to 900° C. A calcining time may be from 1 hour to 3 hours. The calcined product is pulverized in an organic solvent or water. A pulverization time may be from 5 hours to 30 hours. A pulverization means may be a ball mill. After the calcined product is pulverized and dried, a powder of the calcined product is obtained by granulating the calcined product added with a binder solution. The powder of the calcined product is subjected to press molding to obtain a block-shaped compact.

The binder in the compact volatilizes by heating the block-shaped compact. A heating temperature may be from 400° C. to 800° C. A heating time may be from 2 hours to 4 hours. Subsequently, the compact is sintered to obtain a target. A sintering temperature may be from 800° C. to 1100° C. A sintering time may be from 2 hours to 4 hours. A temperature increasing rate and a temperature decreasing rate of the compact in the sintering process may be, for example, from 50° C./hr to 300° C./hr. An average grain size of crystal grains of the metal oxide contained in the target may be, for example, from 1 μm to 20 μm.

The piezoelectric thin film 3 may be formed by a vapor deposition method using the above-described target. In the vapor deposition method, elements constituting the target are evaporated in a vacuum atmosphere. The evaporated elements are attached to and deposited on any of the surfaces of the second intermediate layer 6, the first electrode layer 2, or the crystalline substrate 1, so that the piezoelectric thin film 3 grows. The vapor deposition method may be, for example, a sputtering method, an electron beam vapor deposition method, a chemical vapor deposition method, or a pulsed-laser deposition method. In the following, the pulsed-laser deposition method is referred to as a PLD method. By using these vapor deposition methods, it is possible to form the piezoelectric thin film 3 that is dense at atomic level, and segregation of elements in the piezoelectric thin film 3 is suppressed. An excitation source is different depending on the type of the vapor deposition method. An excitation source of a sputtering method is an Ar plasma. An excitation source of an electron beam vapor deposition method is an electron beam. An excitation source of a PLD method is laser light (for example, excimer laser). When these excitation sources are irradiated to the target, elements constituting the target evaporate.

Among the vapor deposition methods described above, the PLD method is relatively excellent in the following points. In the PLD method, respective elements constituting a target can be instantly and evenly made into plasma by a pulsed-laser. Therefore, the piezoelectric thin film 3 having substantially or completely the same composition as the target is easily formed. Furthermore, in the PLD method, a thickness of the piezoelectric thin film 3 is easily controlled by changing the number of shots of laser pulse.

The piezoelectric thin film 3 may be an epitaxial film. That is, the piezoelectric thin film 3 may be formed by epitaxial growth. The piezoelectric thin film 3 excellent in the crystalline orientation is easily formed by epitaxial growth. In a case where the piezoelectric thin film 3 is formed by the PLD method, the piezoelectric thin film 3 is likely to be formed by epitaxial growth.

In the PLD method, the piezoelectric thin film 3 may be formed while heating the crystalline substrate 1 and the first electrode layer 2 in a vacuum chamber. A temperature (film-forming temperature) of the crystalline substrate 1 and the first electrode layer 2 may be, for example, from 300° C. to 800° C., from 500° C. to 700° C., or from 500° C. to 600° C. As the film-forming temperature increases, cleanliness of the surface of the crystalline substrate 1 or the first electrode layer 2 is improved, and thus the crystallinity of the piezoelectric thin film 3 is enhanced, so that the orientation degree of the (001) plane of the piezoelectric thin film 3 is likely to increase. In a case where the film-forming temperature is excessively high, Bi or K is likely to be desorbed from the piezoelectric thin film 3, and thus the composition of the piezoelectric thin film 3 is difficult to be controlled.

In the PLD method, an oxygen partial pressure in a vacuum chamber may be, for example, more than 10 mTorr and less than 400 mTorr, from 15 mTorr to 300 mTorr, or from 20 mTorr to 200 mTorr. In other words, the oxygen partial pressure in the vacuum chamber may be, for example, more than 1 Pa and less than 53 Pa, from 2 Pa to 40 Pa, or from 3 Pa to 30 Pa. By maintaining the oxygen partial pressure within the above range, Bi, K, Ti, Mg, Fe, and the element M deposited on the crystalline substrate 1 are likely to be sufficiently oxidized. In a case where the oxygen partial pressure is excessively high, a growth rate of the piezoelectric thin film 3 is likely to decrease, and the orientation degree of the (001) plane in the piezoelectric thin film 3 is likely to decrease.

Parameters other than those above controlled in the PLD method include, for example, a laser oscillation frequency and a distance between a substrate and a target. By controlling these parameters, the crystalline structure and the crystalline orientation of the piezoelectric thin film 3 are easily controlled. For example, in a case where the laser oscillation frequency is 10 Hz or less, the orientation degree of the (001) plane in the piezoelectric thin film 3 is likely to increase.

After growth of the piezoelectric thin film 3, an annealing treatment (heating treatment) of the piezoelectric thin film 3 may be performed. A temperature (annealing temperature) of the piezoelectric thin film 3 in the annealing treatment may be, for example, from 300° C. to 1000° C., from 600° C. to 1000° C., or from 850° C. to 1000° C. The piezoelectric properties of the piezoelectric thin film 3 tend to be further improved by the annealing treatment of the piezoelectric thin film 3. The piezoelectric properties of the piezoelectric thin film 3 are likely to be improved by the annealing treatment particularly at a temperature from 850° C. to 1000° C. However, the annealing treatment is not essential.

For example, the crystalline substrate 1 may be a substrate consisting of a single crystal of Si or a substrate consisting of a single crystal of a compound semiconductor such as GaAs. The crystalline substrate 1 may be a substrate consisting of a single crystal of oxide such as MgO or a perovskite-type oxide (for example, SrTiO₃). For example, a thickness of the crystalline substrate 1 may be from 10 μm to 1000 μm. In a case where the crystalline substrate 1 has conductivity, the crystalline substrate 1 functions as an electrode, and thus the first electrode layer 2 may not be provided. For example, the crystalline substrate 1 having conductivity may be a single crystal of SrTiO₃ doped with niobium (Nb). A SOI (Silicon-on-Insulator) substrate may be used as the crystalline substrate 1.

The crystal orientation of the crystalline substrate 1 may be equal to a normal direction of a surface of the crystalline substrate 1. That is, the surface of the crystalline substrate 1 may be parallel to a lattice plane of the crystalline substrate 1. The crystalline substrate 1 may be a uniaxially oriented substrate. For example, one lattice plane selected from the group consisting of a (100) plane, a (001) plane, a (110) plane, a (101) plane, and a (111) plane may be parallel to the surface of the crystalline substrate 1. In a case where the (100) plane of the crystalline substrate 1 (for example, Si) is parallel to the surface of the crystalline substrate 1, the (001) plane of the crystal in the piezoelectric thin film 3 is likely to be oriented in the normal direction dn of the surface of the piezoelectric thin film 3.

As described above, the first intermediate layer 5 may be disposed between the crystalline substrate 1 and the first electrode layer 2. For example, the first intermediate layer 5 may contain at least one selected from the group consisting of titanium (Ti), chromium (Cr), titanium oxide (TiO₂), silicon oxide (SiO₂), and zirconium oxide (ZrO₂). The first electrode layer 2 is likely to be in close contact with the crystalline substrate 1 with the first intermediate layer 5 interposed therebetween. The first intermediate layer 5 may be crystalline. A lattice plane of the first intermediate layer 5 may be oriented in the normal direction of the surface of the crystalline substrate 1. Both of the lattice plane of the crystalline substrate 1 and the lattice plane of the first intermediate layer 5 may be oriented in the normal direction on the surface of the crystalline substrate 1. The formation method of the first intermediate layer 5 may be a sputtering method, a vacuum deposition method, a printing method, a spin coat method, or a sol-gel method.

The first intermediate layer 5 may contain ZrO₂ and an oxide of a rare-earth element. When the first intermediate layer 5 contains ZrO₂ and an oxide of a rare-earth element, the first electrode layer 2 consisting of a platinum crystal is likely to be formed on a surface of the first intermediate layer 5, the (002) plane of the platinum crystal is likely to be oriented in the normal direction D_{N} of the surface of the first electrode layer 2, and the (200) plane of the platinum crystal is likely to be oriented in the in-plane direction of the surface of the first electrode layer 2. The rare-earth element may be at least one element selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). The first intermediate layer 5 may consist of yttria-stabilized zirconia (ZrO₂ added with Y₂O₃). When the first intermediate layer 5 consists of yttria-stabilized zirconia, the first electrode layer 2 consisting of a platinum crystal is likely to be formed on the surface of the first intermediate layer 5, the (002) plane of the platinum crystal is likely to be oriented in the normal direction D_{N} of the surface of the first electrode layer 2, and the (200) plane of the platinum crystal is likely to be oriented in the in-plane direction of the surface of the first electrode layer 2. From the same reasons, the first intermediate layer 5 may have a first layer consisting of ZrO₂ and a second layer consisting of Y₂O₃. The first layer may be stacked directly on the surface of the crystalline substrate 1, the second layer may be stacked directly on the surface of the first layer, and the first electrode layer 2 may be stacked directly on the surface of the second layer.

For example, the first electrode layer 2 may consist of at least one metal selected from the group consisting of platinum (Pt), palladium (Pd), rhodium (Rh), gold (Au), ruthenium (Ru), iridium (Ir), molybdenum (Mo), titanium (Ti), tantalum (Ta), and nickel (Ni). The first electrode layer 2 may consist of, for example, a conductive metal oxide such as strontium ruthenium oxide (SrRuO₃), lanthanum nickel oxide (LaNiO₃), or lanthanum strontium cobalt oxide ((La,Sr)CoO₃). The first electrode layer 2 may be crystalline. A lattice plane of the first electrode layer 2 may be oriented in the normal direction of the surface of the crystalline substrate 1. The lattice plane of the first electrode layer 2 may be substantially or completely parallel to the surface of the crystalline substrate 1. Both of the lattice plane of the crystalline substrate 1 and the lattice plane of the first electrode layer 2 may be oriented in the normal direction on the surface of the crystalline substrate 1. The lattice plane of the first electrode layer 2 may be substantially or completely parallel to the lattice plane of the perovskite-type oxide oriented in the piezoelectric thin film 3. For example, a thickness of the first electrode layer 2 may be from 1 nm to 1.0 μm. The formation method of the first electrode layer 2 may be a sputtering method, a vacuum deposition method, a printing method, a spin coat method, or a sol-gel method. In the case of a printing method, a spin coat method, or a sol-gel method, the heating treatment (annealing) of the first electrode layer 2 may be performed in order to enhance the crystallinity of the first electrode layer 2.

The first electrode layer 2 may contain a platinum crystal. The first electrode layer 2 may consist only of a platinum crystal. The platinum crystal is a cubic crystal having a face-centered cubic lattice structure. The (002) plane of the platinum crystal may be oriented in the normal direction D_{N} of the surface of the first electrode layer 2, and the (200) plane of the platinum crystal may be oriented in the in-plane direction of the surface of the first electrode layer 2. In other words, the (002) plane of the platinum crystal may be substantially or completely parallel to the surface of the first electrode layer 2, and the (200) plane of the platinum crystal may be substantially or completely perpendicular to the surface of the first electrode layer 2. In a case where the (002) plane and the (200) plane of the platinum crystal constituting the first electrode layer 2 have the above-described orientation, the piezoelectric thin film 3 is likely to grow epitaxially on the surface of the first electrode layer 2, and a lattice stress due to the lattice mismatch between the first electrode layer 2 and the piezoelectric thin film 3 is likely to act on the piezoelectric thin film 3. The lattice stress may be a compressive stress in the in-plane direction of the surface of the piezoelectric thin film 3. As a result, the piezoelectric thin film 3 is likely to contain at least one crystal selected from the group consisting of a tetragonal crystal and an orthorhombic crystal, and the (001) plane of the crystal is likely to be preferentially oriented in the normal direction dn of the surface of the piezoelectric thin film 3. As a result, the piezoelectric thin film element 10 is likely to have excellent piezoelectric properties and ferroelectricity.

The second intermediate layer 6 may be disposed between the first electrode layer 2 and the piezoelectric thin film 3. The second intermediate layer 6 may contain, for example, at least one compound selected from the group consisting of SrRuO₃, LaNiO₃, and (La,Sr)CoO₃. The piezoelectric thin film 3 is likely to be in close contact with the first electrode layer 2 with the second intermediate layer 6 interposed therebetween. The second intermediate layer 6 may be crystalline. In a case where the second intermediate layer 6 contains at least one of SrRuO₃ and LaNiO₃, the lattice stress due to the lattice mismatch between the second intermediate layer 6 and the piezoelectric thin film 3 is likely to act on the piezoelectric thin film 3. The lattice stress may be a compressive stress in the in-plane direction of the surface of the piezoelectric thin film 3. As a result, the piezoelectric thin film 3 is likely to contain at least one crystal selected from the group consisting of a tetragonal crystal and an orthorhombic crystal, and the (001) plane of the crystal is likely to be preferentially oriented in the normal direction dn of the surface of the piezoelectric thin film 3. As a result, the piezoelectric thin film element 10 is likely to have excellent piezoelectric properties and ferroelectricity. A lattice plane of the second intermediate layer 6 may be oriented in the normal direction D_{N} of the surface of the first electrode layer 2. Both of the lattice plane of the crystalline substrate 1 and the lattice plane of the second intermediate layer 6 may be oriented in the normal direction D_{N} of the surface of the first electrode layer 2. The formation method of the second intermediate layer 6 may be a sputtering method, a vacuum deposition method, a printing method, a spin coat method, or a sol-gel method.

The second electrode layer 4 may consist of, for example, at least one metal selected from the group consisting of Pt, Pd, Rh, Au, Ru, Ir, Mo, Ti, Ta, and Ni. The second electrode layer 4 may consist of, for example, at least one conductive metal oxide selected from the group consisting of LaNiO₃, SrRuO₃, and (La,Sr)CoO₃. The second electrode layer 4 may be crystalline. A lattice plane of the second electrode layer 4 may be oriented in the normal direction dn of the surface of the piezoelectric thin film 3. The lattice plane of the second electrode layer 4 may be substantially or completely parallel to the surface of the piezoelectric thin film 3. The lattice plane of the second electrode layer 4 may be substantially or completely parallel to the (001) plane oriented in the piezoelectric thin film 3. For example, a thickness of the second electrode layer 4 may be from 1 nm to 1.0 μm. The formation method of the second electrode layer 4 may be a sputtering method, a vacuum deposition method, a printing method, a spin coat method, or a sol-gel method. In the case of a printing method, a spin coat method, or a sol-gel method, the heating treatment (annealing) of the second electrode layer 4 may be performed in order to enhance the crystallinity of the second electrode layer 4.

A third intermediate layer may be disposed between the piezoelectric thin film 3 and the second electrode layer 4. The second electrode layer 4 is likely to be in close contact with the piezoelectric thin film 3 with the third intermediate layer interposed therebetween. Due to the lattice mismatch between the crystalline third intermediate layer and the piezoelectric thin film 3, the above-described lattice stress is likely to act on the piezoelectric thin film 3. As a result, the piezoelectric thin film 3 is likely to contain at least one crystal selected from the group consisting of a tetragonal crystal and an orthorhombic crystal, and the (001) plane of the crystal is likely to be preferentially oriented in the normal direction dn of the surface of the piezoelectric thin film 3. As a result, the piezoelectric thin film element 10 is likely to have excellent piezoelectric properties and ferroelectricity. The composition, crystalline structure, and formation method of the third intermediate layer may be the same as those of the second intermediate layer 6.

At least a part or the whole of the surface of the piezoelectric thin film element 10 may be coated with a protective film. By coating the piezoelectric thin film element 10 with the protective film, for example, the moisture resistance of the piezoelectric thin film element 10 is improved.

The applications of the piezoelectric thin film element according to the present embodiment are various. For example, the piezoelectric thin film element may be a part or the whole of one device selected from the group consisting of a piezoelectric actuator, a piezoelectric sensor, a piezoelectric transducer, a piezoelectric microphone, a harvester, an oscillator, a resonator, an acoustic multi-layer film, a pyroelectric element, and a filter. For example, the piezoelectric actuator may be used in haptics. That is, the piezoelectric actuator may be used in various devices where a feedback due to cutaneous sensation (haptic sense) is required. For example, the device requiring the feedback due to cutaneous sensation may be a wearable device, a touch pad, a display, or a game controller. For example, the piezoelectric actuator may be used in ahead assembly, ahead stack assembly, or a hard disk drive. For example, the piezoelectric actuator may be used in a printer head or an ink jet printer. For example, the piezoelectric actuator may be used in a piezoelectric switch. For example, the piezoelectric sensor or the piezoelectric transducer may be used in a gyroscope sensor, a pressure sensor, a pulse sensor, an ultrasonic sensor, an ultrasonic transducer, an infrared sensor, or a shock sensor. The ultrasonic transducer may be a piezoelectric micromachined ultrasonic transducer (PMUT). A product to which the piezoelectric micromachined ultrasonic transducer is applied may be a biometric sensor such as a fingerprint sensor and an ultrasonic vessel authentication sensor, a medical or healthcare sensor, or a ToF (Time of Flight) sensor. For example, the filter may be a BAW (Bulk Acoustic Wave) filter or an SAW (Surface Acoustic Wave) filter. Each of the above-described piezoelectric thin film elements may be a part or the whole of micro electro mechanical systems (MEMS). Each of the above-described piezoelectric thin film element may be a wearable device or a portable device.

A piezoelectric transducer according to the present embodiment contains the above-described piezoelectric thin film or piezoelectric thin film element. FIG. 6 illustrates a schematic cross-section of an ultrasonic transducer 10a as an example of the piezoelectric transducer. The cross-section of this ultrasonic transducer 10a is substantially or completely parallel to the normal direction dn of the surface of the piezoelectric thin film 3. The ultrasonic transducer 10a may contain substrates 1a and 1b, the first electrode layer 2 provided on the substrates 1a and 1b, the piezoelectric thin film 3 stacked on the first electrode layer 2, and the second electrode layer 4 stacked on the piezoelectric thin film 3. An acoustic cavity 1c may be provided below the piezoelectric thin film 3. An ultrasonic signal is transmitted or received by deflection or vibration of the piezoelectric thin film 3. The first intermediate layer may be interposed between the substrates 1a and 1b and the first electrode layer 2. The second intermediate layer may be interposed between the first electrode layer 2 and the piezoelectric thin film 3. The third intermediate layer may be interposed between the piezoelectric thin film 3 and the second electrode layer 4.

It is to be understood that not all aspects, advantages and features described herein may necessarily be achieved by, or included in, any one particular example. Indeed, having described and illustrated various examples herein, it should be apparent that other examples may be modified in arrangement and detail.

### EXAMPLES

Hereinafter, the present invention will be described in more detail with reference to Examples; however, the present invention is not limited to these Examples.

### Example 1

A crystalline substrate consisting of a single crystal of Si was used in the production of a piezoelectric thin film element of Example 1. A (100) plane of Si was parallel to the surface of the crystalline substrate. The crystalline substrate had a square shape of 20 mm×20 mm. A thickness of the crystalline substrate was 500 μm.

A crystalline first intermediate layer consisting of ZrO₂ and Y₂O₃ was formed on the entire surface of the crystalline substrate in a vacuum chamber. The first intermediate layer was formed by a sputtering method. A thickness of the first intermediate layer was 30 nm.

A first electrode layer consisting of a Pt crystal was formed on the entire surface of the first intermediate layer in a vacuum chamber. The first electrode layer was formed by a sputtering method. A thickness of the first electrode layer was 200 nm. A temperature (film-forming temperature) of the crystalline substrate in the formation process of the first electrode layer was maintained at 500° C.

An X-ray diffraction (XRD) pattern of the first electrode layer was measured by out-of-plane measurement on the surface of the first electrode layer. Another XRD pattern of the first electrode layer was measured by in-plane measurement in the surface of the first electrode layer. In the measurement of these XRD patterns, an X-ray diffraction apparatus (SmartLab) manufactured by Rigaku Corporation was used. Measurement conditions were set so that the intensity of each peak in the XRD patterns would be at least three orders of magnitude higher than the background intensity. A diffracted X-ray peak of the (002) plane of the Pt crystal was detected by out-of-plane measurement. That is, the (002) plane of the Pt crystal was oriented in the normal direction of the surface of the first electrode layer. A diffracted X-ray peak of the (200) plane of the Pt crystal was detected by in-plane measurement. That is, the (200) plane of the Pt crystal was oriented in the in-plane direction of the surface of the first electrode layer.

A piezoelectric thin film was formed on the entire surface of the first electrode layer in a vacuum chamber. The piezoelectric thin film was formed by a PLD method. A thickness of the piezoelectric thin film was 2000 nm. A temperature (film-forming temperature) of the crystalline substrate in the formation process of the piezoelectric thin film was maintained at 500° C. An oxygen partial pressure in the vacuum chamber in the formation process of the piezoelectric thin film was maintained at 10 Pa. As a raw material for the piezoelectric thin film, a target (sintered body of raw material powders) was used. In the production of the target, the compounding ratio of the raw material powders (bismuth oxide, potassium carbonate, titanium oxide, magnesium oxide, iron oxide, and gallium oxide) was adjusted to correspond to the intended composition of the piezoelectric thin film. The intended composition of the piezoelectric thin film was represented by Chemical Formula 1A below. That is, the composition of the target was represented by Chemical Formula 1A below. A value of each of x, y, z, α, β, and γ in Chemical Formula 1A below was a value shown in Table 1 below.

x(B_{1-α}K_{α})TiO₃-yBi(Ti_{1-β}Mg_{β})O₃-zBi(Fe_{1-γ}M_{γ})O₃ (1A)

The composition of the piezoelectric thin film was analyzed by X-Ray fluorescence spectroscopy (XRF method). An apparatus PW2404 manufactured by Philips Japan, Ltd. was used for the analysis. As a result of analysis, the composition of the piezoelectric thin film of Example 1 was represented by Chemical Formula 1A above, and the value of each of x, y, z, α, β, and γ in Chemical Formula 1A above was consistent with the value shown in Table 1 below. That is, the composition of the piezoelectric thin film was consistent with the composition of the target.

An XRD pattern of the piezoelectric thin film was measured by out-of-plane measurement on the surface of the piezoelectric thin film. Another XRD pattern of the piezoelectric thin film was measured by in-plane measurement in the surface of the piezoelectric thin film. The measurement apparatus and the measurement conditions of the XRD patterns were the same conditions as those described above.

The XRD patterns of the piezoelectric thin film indicated that the piezoelectric thin film is composed of a crystal of a perovskite-type oxide.

A lattice constant c of the crystal in the normal direction of the surface of the piezoelectric thin film was measured by the out-of-plane measurement. The lattice constant c is restated as a spacing of lattice planes parallel to the surface of the piezoelectric thin film. Lattice constants a and b of the crystal in a direction parallel to the surface of the piezoelectric thin film was measured by the in-plane measurement. The lattice constants a and b are restated as a spacing of lattice planes perpendicular to the surface of the piezoelectric thin film. a and b were substantially equal to each other. Both a and b were smaller than c. That is, at least a part of the crystal contained in the piezoelectric thin film was a tetragonal crystal in which c/a is more than 1.

A diffracted X-ray peak of the (001) plane of the crystal of the perovskite-type oxide was detected by the out-of-plane measurement. Based on the XRD pattern, the orientation degree of the (001) plane of the crystal was calculated. As described above, the orientation degree of the (001) plane is represented as 100×I₍₀₀₁₎/(I₍₀₀₁₎+I₍₁₁₀₎+I₍₁₁₁₎). The orientation degree of the (001) plane in the normal direction dn of the surface of the piezoelectric thin film was 90% or more. That is, the (001) plane of the crystal was preferentially oriented in the normal direction of the surface of the piezoelectric thin film. The lattice plane preferentially oriented in the normal direction dn of the surface of the piezoelectric thin film (a lattice plane having an orientation degree of 90% or more) is referred to as “oriented plane” in each Table below.

By the method described above, a laminate composed of the crystalline substrate, the first intermediate layer stacked on the crystalline substrate, the first electrode layer stacked on the first intermediate layer, and the piezoelectric thin film stacked on the first electrode layer was produced. The following step was further performed using the laminate.

A second electrode layer consisting of Pt was formed on the entire surface of the piezoelectric thin film in a vacuum chamber. The second electrode layer was formed by a sputtering method. A temperature of the crystalline substrate in the formation process of the second electrode layer was maintained at 500° C. A thickness of the second electrode layer was 200 nm.

Through the steps described above, a laminate composed of the crystalline substrate, the first intermediate layer stacked on the crystalline substrate, the first electrode layer stacked on the first intermediate layer, the piezoelectric thin film stacked on the first electrode layer, and the second electrode layer stacked on the piezoelectric thin film was produced. In the subsequent photolithography, patterning of the laminate structure on the crystalline substrate was performed. After the patterning, the laminate was cut by dicing.

Through the steps described above, a piezoelectric thin film element in a strip form of Example 1 was obtained. The piezoelectric thin film element was composed of the crystalline substrate, the first intermediate layer stacked on the crystalline substrate, the first electrode layer stacked on the first intermediate layer, the piezoelectric thin film stacked on the first electrode layer, and the second electrode layer stacked on the piezoelectric thin film. An area of the movable part of the piezoelectric thin film was 20 mm×1.0 mm.

[Measurement of Piezoelectric Strain Constant d_{33,f}]

The piezoelectric strain constant d_{33,f} of the piezoelectric thin film was measured using the piezoelectric thin film element of Example 1. An apparatus including an atomic force microscope (AFM) and a ferroelectric material evaluation system in combination was used in the measurement of d_{33,f}. The atomic force microscope was SPA-400 manufactured by Seiko Instruments Inc., and the ferroelectric material evaluation system was FCE manufactured by TOYO Corporation. A frequency of an alternating electric field (alternating voltage) in the measurement of d_{33,f} was 5 Hz. The maximum value of the voltage applied to the piezoelectric thin film was 20 V. A unit of d_{33,f} is pm/V. d_{33,f} of Example 1 is shown in Table 1 below.

### Examples 2 to 18 and Comparative Examples 1 to 4

In the production of the target of each of Examples 2 to 18 and Comparative Examples 1 to 4, the compounding ratio of the raw material powders (bismuth oxide, potassium carbonate, titanium oxide, magnesium oxide, iron oxide, and gallium oxide) was adjusted to correspond to the intended composition of the piezoelectric thin film.

As a raw material for the target of Comparative Example 1, potassium carbonate was not used.

As a raw material for the target of Comparative Example 2, magnesium oxide was not used.

As a raw material for the target of Comparative Example 3, gallium oxide was not used.

As a raw material for the target of Comparative Example 4, iron oxide was not used.

A piezoelectric thin film element of each of Examples 2 to 18 and Comparative Examples 1 to 4 was produced by the same method as in Example 1, except that the composition of the target used for forming the piezoelectric thin film was different.

XRD patterns of the first electrode layer of each of Examples 2 to 18 and Comparative Examples 1 to 4 were measured by the same method as in Example 1. In any cases of Examples 2 to 18 and Comparative Examples 1 to 4, the (002) plane of the Pt crystal constituting the first electrode layer was oriented in the normal direction of the surface of the first electrode layer, and the (200) plane of the Pt crystal was oriented in the in-plane direction of the surface of the first electrode layer.

The composition of the piezoelectric thin film of each of Examples 2 to 18 and Comparative Examples 1 to 4 was analyzed by the same method as in Example 1. In any cases of Examples 2 to 18 and Comparative Examples 1 to 4, the composition of the piezoelectric thin film was consistent with the composition (Chemical Formula 1A above) of the target. In the case of each of Examples 2 to 18 and Comparative Examples 1 to 4, a value of each of x, y, z, α, β, γ, and δ in Chemical Formula 1A was a value shown in Table 1 below. x, y, and z of each of Examples 1 to 14 are shown as coordinates (x, y, z) in FIG. 5 (triangular coordinate system).

The coordinates A in FIG. 5 correspond to Example 1.

The coordinates B in FIG. 5 correspond to Example 2.

The coordinates C in FIG. 5 correspond to Example 3.

The coordinates D in FIG. 5 correspond to Example 4.

The coordinates E in FIG. 5 correspond to Example 5.

The coordinates F in FIG. 5 correspond to Example 6.

The coordinates G in FIG. 5 correspond to Example 7.

The coordinates H in FIG. 5 correspond to Example 8.

The coordinates I in FIG. 5 correspond to Example 9.

The coordinates J in FIG. 5 correspond to Example 10.

The coordinates K in FIG. 5 correspond to Example 11.

The coordinates L in FIG. 5 correspond to Example 12.

The coordinates M in FIG. 5 correspond to Example 13.

The coordinates O in FIG. 5 correspond to Example 14.

XRD patterns of the piezoelectric thin film of each of Examples 2 to 18 and Comparative Examples 1 to 4 were measured by the same method as in Example 1. Any of the XRD patterns of Examples 2 to 18 and Comparative Examples 1 to 4 indicated that the piezoelectric thin film is composed of a crystal of a perovskite-type oxide. In any cases of Examples 2 to 18 and Comparative Examples 1 to 4, at least a part of the crystal contained in the piezoelectric thin film was a tetragonal crystal. In any cases of Examples 2 to 18 and Comparative Examples 1 to 4, the (001) plane of the crystal was preferentially oriented in the normal direction of the surface of the piezoelectric thin film.

The piezoelectric strain constant d_{33,f} of the piezoelectric thin film of each of Examples 2 to 18 and Comparative Examples 1 to 4 was measured by the same method as in Example 1. d_{33,f} of each of Examples 2 to 18 and Comparative Examples 1 to 4 is shown in Table 1 below.

### Comparative Example 5

The target of Comparative Example 5 did not contain bismuth. The target of Comparative Example 5 had the composition represented by Chemical Formula 5 below. Each numerical value in Chemical Formula 5 below represents a molar ratio. A thin film and a thin film element of Comparative Example 5 were produced by the same method as in Example 1, except that the composition of the target used for forming the thin film was different.

Analysis and measurement for the thin film and the thin film element of Comparative Example 5 were performed by the same method as in Example 1. Also in the case of Comparative Example 5, the (002) plane of the Pt crystal constituting the first electrode layer was oriented in the normal direction of the surface of the first electrode layer, and the (200) plane of the Pt crystal was oriented in the in-plane direction of the surface of the first electrode layer. The composition of the thin film of Comparative Example 5 was consistent with the composition of the target of Comparative Example 5. The thin film of Comparative Example 5 was not a crystal having an oriented lattice plane and did not have piezoelectric properties.

0.20MgTiO₃-0.10K₂O-0.20TiO₂-0.50(Fe_{0.9}Ga_{0.1})₂O₃ (5)

TABLE 1

| Table 1 | x | y | z | α | β | γ | Oriented plane | d_{33,f} |
|---|---|---|---|---|---|---|---|---|
| Example 1 | 0.250 | 0.050 | 0.700 | 0.500 | 0.500 | 0.400 | (001) | 192 |
| Example 2 | 0.450 | 0.250 | 0.300 | 0.500 | 0.500 | 0.400 | (001) | 183 |
| Example 3 | 0.200 | 0.500 | 0.300 | 0.500 | 0.500 | 0.050 | (001) | 181 |
| Example 4 | 0.050 | 0.250 | 0.700 | 0.500 | 0.500 | 0.100 | (001) | 193 |
| Example 5 | 0.400 | 0.200 | 0.400 | 0.500 | 0.500 | 0.100 | (001) | 185 |
| Example 6 | 0.200 | 0.400 | 0.400 | 0.500 | 0.500 | 0.100 | (001) | 184 |
| Example 7 | 0.300 | 0.100 | 0.600 | 0.500 | 0.500 | 0.100 | (001) | 191 |
| Example 8 | 0.100 | 0.300 | 0.600 | 0.500 | 0.500 | 0.100 | (001) | 188 |
| Example 9 | 0.200 | 0.200 | 0.600 | 0.500 | 0.500 | 0.100 | (001) | 194 |
| Example 10 | 0.150 | 0.150 | 0.700 | 0.500 | 0.500 | 0.050 | (001) | 191 |
| Example 11 | 0.350 | 0.150 | 0.500 | 0.500 | 0.500 | 0.200 | (001) | 190 |
| Example 12 | 0.150 | 0.350 | 0.500 | 0.500 | 0.500 | 0.300 | (001) | 182 |
| Example 13 | 0.250 | 0.250 | 0.500 | 0.500 | 0.500 | 0.250 | (001) | 181 |
| Example 14 | 0.350 | 0.350 | 0.300 | 0.500 | 0.500 | 0.100 | (001) | 180 |
| Example 15 | 0.200 | 0.200 | 0.600 | 0.500 | 0.500 | 0.150 | (001) | 192 |
| Example 16 | 0.200 | 0.200 | 0.600 | 0.500 | 0.500 | 0.050 | (001) | 194 |
| Example 17 | 0.200 | 0.200 | 0.600 | 0.500 | 0.500 | 0.200 | (001) | 187 |
| Example 18 | 0.200 | 0.200 | 0.600 | 0.500 | 0.500 | 0.400 | (001) | 185 |
| Comparative | 0.000 | 0.500 | 0.500 | 0.000 | 0.500 | 0.300 | (001) | 45 |
| Example 1 | | | | | | | | |
| Comparative | 0.400 | 0.000 | 0.600 | 0.500 | 0.000 | 0.400 | (001) | 106 |
| Example 2 | | | | | | | | |
| Comparative | 0.300 | 0.500 | 0.200 | 0.500 | 0.500 | 0.000 | (001) | 40 |
| Example 3 | | | | | | | | |
| Comparative | 0.400 | 0.400 | 0.200 | 0.500 | 0.500 | 1.000 | (001) | 60 |
| Example 4 | | | | | | | | |

### Comparative Examples 6 to 8

The oxygen partial pressure in the vacuum chamber in the formation process of the piezoelectric thin film of Comparative Example 6 was maintained at 1 Pa.

The oxygen partial pressure in the vacuum chamber in the formation process of the piezoelectric thin film of Comparative Example 7 was maintained at 20 Pa.

The oxygen partial pressure in the vacuum chamber in the formation process of the piezoelectric thin film of Comparative Example 8 was maintained at 0.1 Pa.

A piezoelectric thin film element of each of Comparative Examples 6 to 8 was produced by the same method as in Example 9, except for the oxygen partial pressure in the formation process of the piezoelectric thin film.

XRD patterns of the first electrode layer of each of Comparative Examples 6 to 8 were measured by the same method as in Example 1. In any cases of Comparative Examples 6 to 8, the (002) plane of the Pt crystal constituting the first electrode layer was oriented in the normal direction of the surface of the first electrode layer, and the (200) plane of the Pt crystal was oriented in the in-plane direction of the surface of the first electrode layer.

The composition of the piezoelectric thin film of each of Comparative Examples 6 to 8 was analyzed by the same method as in Example 1. In any cases of Comparative Examples 6 to 8, the composition of the piezoelectric thin film was consistent with the composition of the target. That is, the composition of the piezoelectric thin film of each of Comparative Examples 6 to 8 was the same as the composition of the piezoelectric thin film of Example 9.

XRD patterns of the piezoelectric thin film of each of Comparative Examples 6 to 8 were measured by the same method as in Example 1.

Any of the XRD patterns of Comparative Examples 6 to 8 indicated that the piezoelectric thin film is composed of a crystal of a perovskite-type oxide.

In any cases of Comparative Examples 6 to 8, at least a part of the crystal contained in the piezoelectric thin film was a tetragonal crystal.

In the case of Comparative Example 6, the (110) plane of the crystal in the piezoelectric thin film was preferentially oriented in the normal direction of the surface of the piezoelectric thin film.

In the case of Comparative Example 7, the (111) plane of the crystal in the piezoelectric thin film was preferentially oriented in the normal direction of the surface of the piezoelectric thin film.

In the case of Comparative Example 8, a specific lattice plane of the crystal in the piezoelectric thin film was not oriented in the normal direction of the surface of the piezoelectric thin film. That is, in the case of Comparative Example 8, the orientation degree of any lattice plane was less than 50%.

The piezoelectric strain constant d_{33,f} of the piezoelectric thin film of each of Comparative Examples 6 to 8 was measured by the same method as in Example 1. d_{33,f} of each of Comparative Examples 6 to 8 is shown in Table 2 below.

TABLE 2

| Table 2 | x | y | z | α | β | γ | Oriented plane | d_{33,f} |
|---|---|---|---|---|---|---|---|---|
| Example 9 | 0.200 | 0.200 | 0.600 | 0.500 | 0.500 | 0.100 | (001) | 194 |
| Comparative | 0.200 | 0.200 | 0.600 | 0.500 | 0.500 | 0.100 | (110) | 76 |
| Example 6 | | | | | | | | |
| Comparative | 0.200 | 0.200 | 0.600 | 0.500 | 0.500 | 0.100 | (111) | 85 |
| Example 7 | | | | | | | | |
| Comparative | 0.200 | 0.200 | 0.600 | 0.500 | 0.500 | 0.100 | None | 37 |
| Example 8 | | | | | | | | |

### Examples 19 and 20

In the cases of Examples 19 and 20, the second intermediate layer was formed directly on the entire surface of the first electrode layer, and the piezoelectric thin film was formed directly on the entire surface of the second intermediate layer.

The second intermediate layer of Example 19 consisted of crystalline SrRuO₃. A thickness of the second intermediate layer of Example 19 was 50 nm.

The second intermediate layer of Example 20 consisted of crystalline LaNiO₃. A thickness of the second intermediate layer of Example 20 was 20 nm.

“SRO” in Table 3 below means SrRuO₃. “LNO” in Table 3 below means LaNiO₃.

A piezoelectric thin film element of each of Examples 19 and 20 was produced by the same method as in Example 9, except that the second intermediate layer was formed.

XRD patterns of the first electrode layer of each of Examples 19 and 20 were measured by the same method as in Example 1. In any cases of Examples 19 and 20, the (002) plane of the Pt crystal constituting the first electrode layer was oriented in the normal direction of the surface of the first electrode layer, and the (200) plane of the Pt crystal was oriented in the in-plane direction of the surface of the first electrode layer.

The composition of the piezoelectric thin film of each of Examples 19 and 20 was analyzed by the same method as in Example 1. In any cases of Examples 19 and 20, the composition of the piezoelectric thin film was consistent with the composition of the target. That is, the composition of the piezoelectric thin film of each of Examples 19 and 20 was the same as the composition of the piezoelectric thin film of Example 9.

XRD patterns of the piezoelectric thin film of each of Examples 19 and 20 were measured by the same method as in Example 1.

Any of the XRD patterns of Examples 19 and 20 indicated that the piezoelectric thin film is composed of a crystal of a perovskite-type oxide.

In any cases of Examples 19 and 20, at least a part of the crystal contained in the piezoelectric thin film was a tetragonal crystal.

In any cases of Examples 19 and 20, the (001) plane of the crystal was preferentially oriented in the normal direction of the surface of the piezoelectric thin film.

The piezoelectric strain constant d_{33,f} of the piezoelectric thin film of each of Examples 19 and 20 was measured by the same method as in Example 1. d_{33,f} of each of Examples 19 and 20 is shown in Table 3 below.

TABLE 3

| | | | | | | | | Second | |
|---|---|---|---|---|---|---|---|---|---|
| | | | | | | | | intermediate | |
| Table 3 | x | y | z | α | β | γ | Oriented plane | layer | d_{33,f} |
| Example 9 | 0.200 | 0.200 | 0.600 | 0.500 | 0.500 | 0.100 | (001) | None | 194 |
| Example 19 | 0.200 | 0.200 | 0.600 | 0.500 | 0.500 | 0.100 | (001) | SRO | 196 |
| Example 20 | 0.200 | 0.200 | 0.600 | 0.500 | 0.500 | 0.100 | (001) | LNO | 195 |

### Example 21

In the production process of the piezoelectric thin film element of Example 21, the first intermediate layer was not formed. In the production process of the piezoelectric thin film element of Example 21, the first electrode layer consisting of crystalline SrRuO₃ was formed directly on the entire surface of the crystalline substrate. A thickness of the first electrode layer of Example 21 was 200 nm. A piezoelectric thin film element of Example 21 was produced by the same method as in Example 9 except for these matters.

XRD patterns of the first electrode layer of Example 21 were measured by the same method as in Example 1. The lattice plane of the first electrode layer of Example 21 was not oriented in the in-plane direction of the surface of the first electrode layer. That is, in the case of Example 21, an in-plane orientation of the crystal of the first electrode layer was absent.

The composition of the piezoelectric thin film of Example 21 was analyzed by the same method as in Example 1. The composition of the piezoelectric thin film of Example 21 was consistent with the composition of the target. That is, the composition of the piezoelectric thin film of Example 21 was the same as the composition of the piezoelectric thin film of Example 9.

XRD patterns of the piezoelectric thin film of Example 21 were measured by the same method as in Example 1.

The XRD patterns of Example 21 indicated that the piezoelectric thin film is composed of a crystal of a perovskite-type oxide.

At least a part of the crystal contained in the piezoelectric thin film of Example 21 was a tetragonal crystal.

In the case of Example 21, the (001) plane of the perovskite-type crystal was preferentially oriented in the normal direction of the surface of the piezoelectric thin film.

The piezoelectric strain constant d_{33,f} of the piezoelectric thin film of Example 21 was measured by the same method as in Example 1. d_{33,f} of Example 21 is shown in Table 4 below.

TABLE 4

| | | | | | | | | In-plane | |
|---|---|---|---|---|---|---|---|---|---|
| Table 4 | x | y | z | α | β | γ | Oriented plane | orientation | d_{33,f} |
| Example 9 | 0.200 | 0.200 | 0.600 | 0.500 | 0.500 | 0.100 | (001) | Present | 194 |
| Example 21 | 0.200 | 0.200 | 0.600 | 0.500 | 0.500 | 0.100 | (001) | Absent | 181 |

### Examples 22 and 23

In the production of the target of Example 22, as a raw material, cobalt oxide was further used in addition to gallium oxide.

In the production of the target of Example 23, as a raw material, cobalt oxide was used instead of gallium oxide. That is, in the production of the target of Example 23, gallium oxide was not used.

The composition of the target of each of Examples 22 and 23 was represented by Chemical Formula 1B below. In the case of each of Examples 22 and 23, a value of each of x, y, z, γ, and δ in Chemical Formula 1B below was a value shown in Table 5 below.

x(Bi_{0.5}K_{0.5})TiO₃-yBi(Ti_{0.5}Mg_{0.5})O₃-zBi(Fe_{1-γ}(Ga_{1-δ}Co_{δ})_{γ})O₃ (1B)

A piezoelectric thin film element of each of Examples 22 and 23 was produced by the same method as in Example 1, except that the composition of the target used for forming the piezoelectric thin film was different.

XRD patterns of the first electrode layer of each of Examples 22 and 23 were measured by the same method as in Example 1. In any cases of Examples 22 and 23, the (002) plane of the Pt crystal constituting the first electrode layer was oriented in the normal direction of the surface of the first electrode layer, and the (200) plane of the Pt crystal was oriented in the in-plane direction of the surface of the first electrode layer.

The composition of the piezoelectric thin film of each of Examples 22 and 23 was analyzed by the same method as in Example 1. In any cases of Examples 22 and 23, the composition of the piezoelectric thin film was consistent with the composition of the target. The composition of the piezoelectric thin film of each of Examples 22 and 23 was the same as the composition of the piezoelectric thin film of Example 9, except for Ga_{1-δ}Co_{δ} in Chemical Formula 1B above.

XRD patterns of the piezoelectric thin film of each of Examples 22 and 23 were measured by the same method as in Example 1.

Any of the XRD patterns of Examples 22 and 23 indicated that the piezoelectric thin film is composed of a crystal of a perovskite-type oxide.

In any cases of Examples 22 and 23, at least a part of the crystal contained in the piezoelectric thin film was a tetragonal crystal.

In any cases of Examples 22 and 23, the (001) plane of the crystal was preferentially oriented in the normal direction of the surface of the piezoelectric thin film.

The piezoelectric strain constant d_{33,f} of the piezoelectric thin film of each of Examples 22 and 23 was measured by the same method as in Example 1. d_{33,f} of each of Examples 22 and 23 is shown in Table 5 below.

TABLE 5

| Table 5 | x | y | z | α | β | γ | δ | Oriented plane | d_{33,f} |
|---|---|---|---|---|---|---|---|---|---|
| Example 9 | 0.200 | 0.200 | 0.600 | 0.500 | 0.500 | 0.100 | 0.000 | (001) | 194 |
| Example 22 | 0.200 | 0.200 | 0.600 | 0.500 | 0.500 | 0.100 | 0.500 | (001) | 190 |
| Example 23 | 0.200 | 0.200 | 0.600 | 0.500 | 0.500 | 0.100 | 1.000 | (001) | 192 |

### INDUSTRIAL APPLICABILITY

For example, the piezoelectric thin film element according to an aspect of the present invention may be applied to a piezoelectric transducer, a piezoelectric actuator, and a piezoelectric sensor.

### REFERENCE SIGNS LIST

10: piezoelectric thin film element, 10a: piezoelectric transducer (ultrasonic transducer), 1: crystalline substrate, 2: first electrode layer, 3: piezoelectric thin film, 4: second electrode layer, 5: first intermediate layer, 6: second intermediate layer, D_{N}: normal direction of surface of first electrode layer, dn: normal direction of surface of piezoelectric thin film, uc: unit cell of crystal of perovskite-type oxide.

What is claimed is:

1. A piezoelectric thin film comprising a metal oxide having a perovskite structure, wherein
the metal oxide contains bismuth, potassium, titanium, magnesium, iron, and an element M,
the element M is at least one element selected from the group consisting of gallium and cobalt,
at least a part of the metal oxide is at least one crystal selected from the group consisting of a tetragonal crystal and an orthorhombic crystal, and
a (001) plane of the crystal is oriented in a normal direction of a surface of the piezoelectric thin film.

2. The piezoelectric thin film according to claim 1, wherein the metal oxide is represented by Chemical Formula 1 below,
each of x, y, and z in Chemical Formula 1 below is a positive real number,
x+y+z is 1,
α in Chemical Formula 1 below is more than 0 and less than 1,
β in Chemical Formula 1 below is more than 0 and less than 1,
γ in Chemical Formula 1 below is from 0.05 to 0.40,
M in Chemical Formula 1 below is represented by Ga_{1-δ}Co_{δ}, and
δ is from 0 to 1,
x(B_{1-α}K_{α})TiO₃-yBi(Ti_{1-β}Mg_{β})O₃-zBi(Fe_{1-γ}M_{γ})O₃ (1)

3. The piezoelectric thin film according to claim 2, wherein a three-dimensional coordinate system is composed of an X-axis, a Y-axis, and a Z-axis,
arbitrary coordinates in the coordinate system are represented by (X, Y, Z),
coordinates (x, y, z) in the coordinate system correspond to x, y, and z in Chemical Formula 1 above,
coordinates A in the coordinate system are (0.250, 0.005, 0.700),
coordinates B in the coordinate system are (0.450, 0.250, 0.300),
coordinates C in the coordinate system are (0.200, 0.500, 0.300),
coordinates D in the coordinate system are (0.005, 0.250, 0.700), and
the coordinates (x, y, z) are positioned within a quadrangle with vertexes at the coordinates A, the coordinates B, the coordinates C, and the coordinates D.

4. The piezoelectric thin film according to claim 1, wherein the piezoelectric thin film is an epitaxial film.

5. The piezoelectric thin film according to claim 1, wherein the piezoelectric thin film is a ferroelectric thin film.

6. A piezoelectric thin film element comprising the piezoelectric thin film according to claim 1.

7. The piezoelectric thin film element according to claim 6, comprising:
a crystalline substrate; and
the piezoelectric thin film directly or indirectly stacked on the crystalline substrate.

8. The piezoelectric thin film element according to claim 6, comprising:
a crystalline substrate;
an electrode layer directly or indirectly stacked on the crystalline substrate; and
the piezoelectric thin film directly or indirectly stacked on the electrode layer.

9. The piezoelectric thin film element according to claim 6, comprising:
an electrode layer; and
the piezoelectric thin film directly or indirectly stacked on the electrode layer.

10. The piezoelectric thin film element according to claim 8, further comprising at least one intermediate layer, wherein
the intermediate layer is disposed between the crystalline substrate and the electrode layer.

11. The piezoelectric thin film element according to claim 8, further comprising at least one intermediate layer, wherein
the intermediate layer is disposed between the electrode layer and the piezoelectric thin film.

12. The piezoelectric thin film element according to claim 9, further comprising at least one intermediate layer, wherein
the intermediate layer is disposed between the electrode layer and the piezoelectric thin film.

13. The piezoelectric thin film element according to claim 8, wherein the electrode layer contains a platinum crystal,
a (002) plane of the platinum crystal is oriented in a normal direction of a surface of the electrode layer, and
a (200) plane of the platinum crystal is oriented in an in-plane direction of the surface of the electrode layer.

14. The piezoelectric thin film element according to claim 9, wherein the electrode layer contains a platinum crystal,
a (002) plane of the platinum crystal is oriented in a normal direction of a surface of the electrode layer, and
a (200) plane of the platinum crystal is oriented in an in-plane direction of the surface of the electrode layer.

15. A piezoelectric transducer comprising the piezoelectric thin film according to claim 1.

16. A piezoelectric transducer comprising the piezoelectric thin film element according to claim 6.
